(19) United States
(12) Patent Application Publication
(10) Pub. No.: US 2014/0046014 A1
(43) Pub. Date: Feb. 13, 2014

(54) SILOXANE COMPOUND AND CURED PRODUCT THEREOF

(71) Applicants: Hiroshi Honjo, Chiba-shi (JP); Hiroshi Eguchi, Atlanta, GA (US); Kazuhiro Yamanaka, Tachikawa-shi (JP)

(72) Inventors: Hiroshi Honjo, Chiba-shi (JP); Hiroshi Eguchi, Atlanta, GA (US); Kazuhiro Yamanaka, Tachikawa-shi (JP)

(73) Assignee: Central Glass Company, Limited, Ube-shi (JP)

(21) Appl. No.: 14/112,866

(22) PCT Filed: Apr. 17, 2012
(86) PCT No.: PCT/JP2012/060314

§ 371 Date: Oct. 18, 2013

(30) Foreign Application Priority Data
Apr. 20, 2011 (JP) 2011-094194
Apr. 12, 2012 (JP) 2012-090666

(51) Int. Cl. H01L 23/29

(52) U.S. Cl. CPC H01L 23/296
USPC 526/279; 556/461

(57) ABSTRACT

A siloxane compound according to the present invention is represented by the general formula (1):

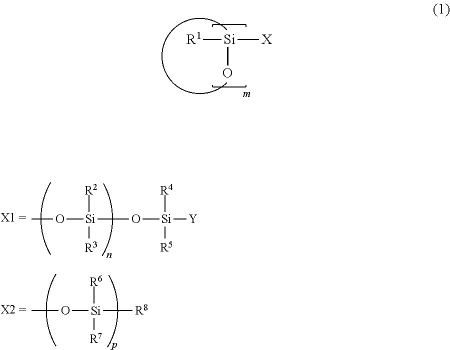

where X are each independently either X1 or X2 with the proviso that at least one of X is X1; R¹ to R⁸ are each independently a hydrogen atom, a C₁-C₈ alkyl, alkenyl or alkynyl group, a phenyl group or a pyridyl group; each of R¹ to R⁵ may have a carbon atom replaced by an oxygen atom and may have an ether bond, a carbonyl group or an ester bond in its structure; m is an integer of 3 to 8; n is an integer of 0 to 9; p is 0 or 1; and Y are each independently a cross-linking group. This siloxane compound according to the present invention has higher heat resistance and flowability and easy formability at lower temperatures as compared to conventional silsesquioxanes.

### TECHNICAL FIELD

The present invention relates to heat-resistant resins, and more particularly, to a siloxane compound and a cured product thereof. The cured product of the siloxane compound according to the present invention is usable as sealing materials and adhesives for semiconductors etc. where heat resistance is required and, when it is colorless and transparent, as optical sealing materials, lens materials, optical thin films, and the like.

### BACKGROUND ART

Sealing materials for semiconductors such as light emitting diodes (LED) are require to have sufficient heat resistance so as to resist heat generated during operation of the semiconductors.

Conventionally, heat-resistant epoxy or silicone resins have been used as semiconductor sealing materials. These conventional epoxy or silicon resin sealing materials are however higher in withstand voltage than silicon (Si) semiconductors and, when used for high-performance semiconductors typified by silicon carbide (SiC) power semiconductors, are not sufficient in heat resistance to resist high heat generated from the power semiconductors and thus tend to be thermally decomposed during operation of the semiconductors.

Polyimide resins are known as higher heat-resistant resins than the epoxy or silicon resins. Patent Document 1 discloses a surface protection film for a semiconductor element, which is formed by curing a polyimide precursor composition under heating at 230 to 300° C. However, the polyimide precursor composition is solid in a low-temperature range at around room temperature (20° C.) and thus is poor in formability.

Silsesquioxanes, which are one class of network-structured polysiloxanes formed by hydrolysis and condensation polymerization of alkyltrialkoxysilane etc., are known as other heat-resistant materials and are usable for various applications because the silsesquioxanes each have an inorganic siloxane structure to which organic functional groups are bonded and enable molecular design that takes advantage of the high heat resistance of the inorganic siloxane structure and the characteristics of the organic functional groups. Further, some of the silsesquioxanes are liquid at room temperature and can be used in potting processes in such a manner that the liquid silsesquioxanes are applied to substrate surfaces and cured by condensation polymerization under heating or ultraviolet irradiation. Patent Documents 2 to 5 and Non-Patent Documents 1 to 6 disclose synthesis methods of silsesquioxanes, respectively.

Various researches have been made on the use of silsesquioxanes, which combine heat resistance with formability, as sealing materials. However, there have not yet been obtained any silsesquioxane sealing materials that are insusceptible to deterioration even when heated under high-temperature conditions of 250° C. or higher over a few thousand hours. There are also problems that, although it is often the case to utilize hydrosilylation in the synthesis of silsesquioxanes that are liquid at room temperature and can be used in potting processes for sealing of semiconductors, the resulting silsesquioxanes may deteriorate in heat resistance due to the formation of alkylene chains such as propylene chain at the respective terminal ends of the silsesquioxanes by the hydrosilylation reaction (see Non-Patent Documents 5 and 6).

### PRIOR ART DOCUMENTS

### Patent Documents

Patent Document 1: Japanese Laid-Open Patent Publication No. 10-270611
Patent Document 2: Japanese Laid-Open Patent Publication No. 2004-143449
Patent Document 3: Japanese Laid-Open Patent Publication No. 2007-15991
Patent Document 4: Japanese Laid-Open Patent Publication No. 2009-191024
Patent Document 5: Japanese Laid-Open Patent Publication No. 2009-269820

### Non-Patent Documents

Non-Patent Document 1: I. Hasegawa et al., Chem. Lett., pp. 1319 (1988)
Non-Patent Document 2: V. Sudarsanan et al., J. Org. Chem., pp. 1892 (2007)
Non-Patent Document 3: M. A. Esteruelas et al., Organometallics, pp. 3891 (2004)
Non-Patent Document 4: A. Mori et al., Chem. Lett., pp. 107 (1995)
Non-Patent Document 5: J. Mater. Chem., 2007, 17, pp. 3575-3580
Non-Patent Document 6: Proc. of SPIE Vol. 6517 651729-0

### SUMMARY OF THE INVENTION

### Problems to be Solved by the Invention

It is an object of the present invention to provide a siloxane compound that has flowability and easy formability at lower temperatures as compared to conventional silsesquioxanes.

### Means for Solving the Problems

The present inventors have found that a siloxane compound in which a specific cross-linking group is bonded to a specific siloxane skeleton is liquid at 60° C. or lower and curable by heating at 150 to 350° C. and thus shows good formability even under relatively low-temperature conditions. The present invention is based on this finding.

Namely, the present invention includes the following aspects.

[Inventive Aspect 1]

A siloxane compound of the general formula (1):

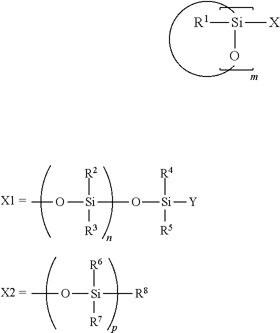

where X are each independently either X1 or X2 with the proviso that at least one of X is X1; R¹ to R⁸ are each independently a hydrogen atom, a C₁-C₈ alkyl, alkenyl or alkynyl group, a phenyl group or a pyridyl group; each of R¹ to R⁵ may have a carbon atom replaced by an oxygen atom and may have an ether bond, a carbonyl group or an ester bond in its structure; m is an integer of 3 to 8; n is an integer of 0 to 9; p is 0 or 1; and Y are each independently a cross-linking group.

[Inventive Aspect 2]

The siloxane compound according to Inventive Aspect 1, wherein Y are each independently a cross-linking group selected from the group consisting of those of the structural formulas (2) to (12):

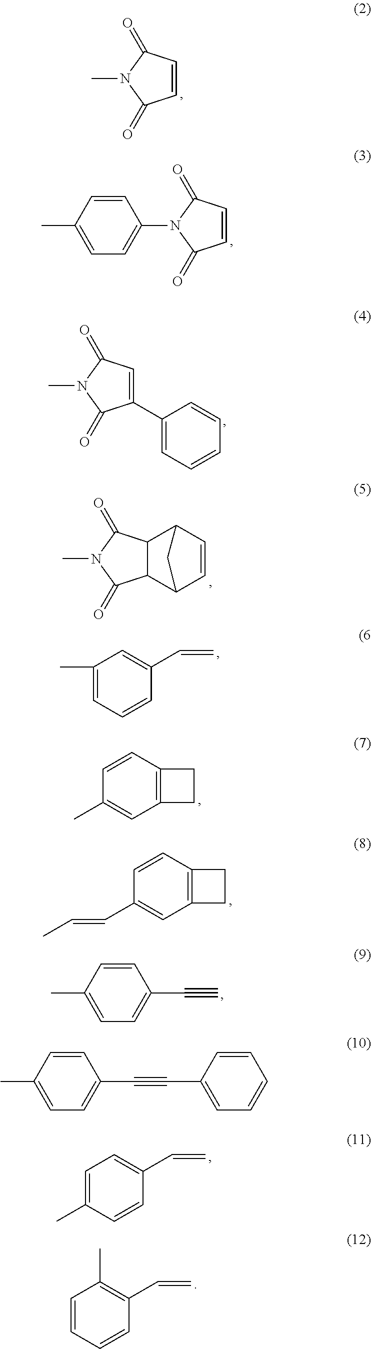

[Inventive Aspect 3]

The siloxane compound according to Inventive Aspect 1 or 2, wherein all of R¹ to R⁸ are methyl n is 0 and p is 0 or 1.

[Inventive Aspect 3]

A cured product obtained by reaction of the cross-linking group of the siloxane compound according to any one of Inventive Aspects 1 to 3.

[Inventive Aspect 4]

A sealing material containing the cured product according to Inventive Aspect 4.

The siloxane compound according to the present invention is liquid at 60° C. or lower and can suitably be used in forming processes, application processes or potting processes. Further, the siloxane compound according to the present invention is formed into a cured product with high heat resistance by cross-linking reaction of the cross-linking groups of the respective siloxane molecules when the siloxane compound is heated solely or in the form of a composition with any other component.

### DETAILED DESCRIPTION OF THE EMBODIMENTS

Hereinafter, the siloxane compound according to the present invention and its synthesis method, features and application for use as semiconductor sealing materials will be sequentially described below.

1. 1. Siloxane Compound

The siloxane compound according to the present invention is represented by the general formula (1). In the following description, the siloxane compound of the general formula (1) is sometimes simply referred to as “siloxane compound (1)”.

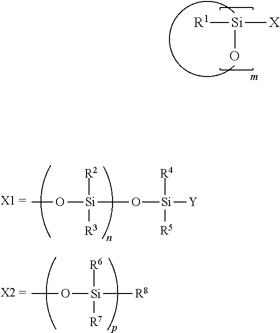

In the general formula (1), X are each independently either X1 or X2 with the proviso that at least one of X is X1; R¹ to R⁸ are each independently a hydrogen atom, a C₁-C₈ alkyl, alkenyl or alkynyl group, a phenyl group or a pyridyl group; each of R¹ to R⁸ may have a carbon atom replaced by an oxygen atom and may have an ether bond, a carbonyl group or an ester bond in its structure; m is an integer of 3 to 8; n is an integer of 0 to 9; p is 0 or 1; and Y are each independently a cross-linking group.

Examples of the C₁-C₈ alkyl group are methyl, ethyl, 1-propyl, 2-propyl, n-butyl and sec-butyl. As the alkyl group, methyl is preferred for the reason that the siloxane compound (1) with a methyl group is easy to synthesize.

Examples of the C₁-C₈ alkenyl group are vinyl, allyl, methacryloyl, acryloyl, styrenyl and norbornanyl. As the alkenyl group, vinyl or methacryloyl is preferred for the reason that the siloxane compound (1) with a vinyl group or methacryloyl group is easy to synthesize.

Examples of the C₁-C₈ alkynyl group are ethynyl and phenylethynyl. As the alkynyl group, phenylethynyl is preferred for the reason that the siloxane compound (1) with a phenylethynyl group is easy to synthesize.

For the same reasons as above, it is preferable that: the phenyl group is a normal phenyl group of 6 carbon atoms; and the pyridyl group is a normal pyridyl group of 5 carbon atoms. The phenyl group and the pyridyl group are preferably unsubstituted although the phenyl group and the pyridyl group may have substituents.

For viscosity adjustment, any carbon atom of the alkyl, alkenyl, alkynyl, phenyl or pyridyl group may be replaced by an oxygen atom to form an ether bond, a carbonyl group or an ester bond in the molecular structure. The above functional bond or group is effective in adjusting the viscosity of the siloxane compound (1).

In the siloxane compound (1), the cross-linking group Y preferably contains a ring structure such as aromatic ring structure or heterocyclic structure in order to secure heat resistance. Herein, a reactive moiety of the cross-linking group is a double-bond group or triple-bond group.

In particular, the cross-linking group Y are each independently at least one selected from the group consisting of cross-linking groups of the structural formulas (2) to (12).

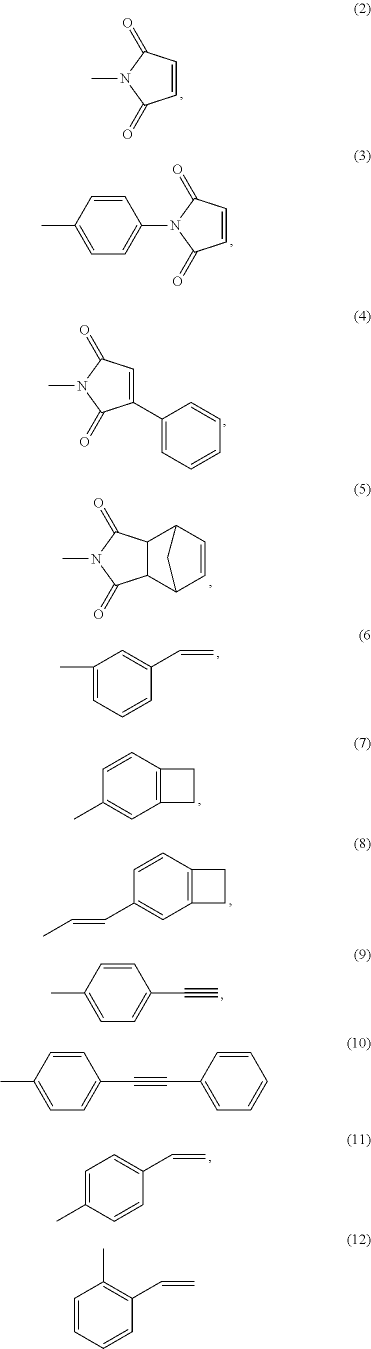

The cross-linking groups of the structural formulas (2) to (12) have heat resistance because of their ring structures and thus do not cause deterioration in the heat resistance of the siloxane compound (1). Further, the cross-linking groups of the structural formulas (2) to (12) each have a double bond or triple bond and allow easy linkage. When the siloxane compound (1) has at least two X1, preferably three or more X1, the siloxane compound (1) can be easily and efficiently formed into a cured product by cross-linking reaction of the cross-linking groups Y of the respective siloxane molecules under heating.

Namely, it is possible to obtain the siloxane compound (1) by bonding of the cross-linking group Y of the structural formulas (2) to (12) to X2 and possible to obtain the cured product of the siloxane compound (1) with very high heat resistance by cross-linking reaction of the cross-linking groups Y of the respective siloxane molecules under heating.

In particular, the siloxane compound (1) can be easily obtained as a single composition by organic synthesis in the case where, in the general formula (1), all of R¹ to R⁸ are methyl; n is 0; p is 0 or 1; and Y are any of the above cross-linking groups. This siloxane compound (1) is liquid in a temperature range from room temperature (20° C.) to 60° C. and thus is suitable for use in semiconductor sealing materials.

60° C. and thus is suitable for use in semiconductor sealing materials.

2. Synthesis of Siloxane Compound (1)

2-1. Synthesis of Siloxane Precursor (A)

First, a siloxane compound of the structural formula (13) is chlorinated as indicated in the following reaction scheme.

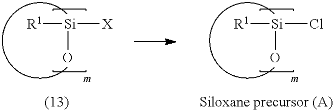

The chlorination of the siloxane compound is conducted by reaction with trichloroisocyanuric acid (see Non-Patent Document 2), hexachlorocyclohexane in the presence of a rhodium catalyst (see Non-Patent Document 3) or chlorine gas etc. Although it is feasible to conduct the chlorination of the siloxane compound by any chlorination technique as disclosed in known publications (e.g. S. Varaprath et al., Journal of Organic Chemistry, Vol. 692, pp. 1892-1897 etc.), the siloxane compound is preferably chlorinated by reaction with trichloroisocyanuric acid or chlorine gas in terms of less by-product and practical cost efficiency.

One specific example of the chlorination is reaction of tetramethyltetrahydrocyclotetrasiloxane with trichloroisocyanuric acid in an organic solvent as indicated in the following reaction scheme.

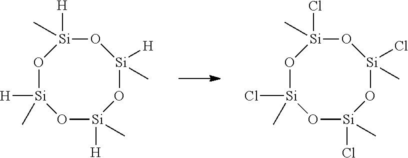 [SMILES: C[SiH]1O[SiH](C)O[SiH](C)O[SiH](C)O1 ; C[Si]1(Cl)O[Si](C)(Cl)O[Si](C)(Cl)O[Si](C)(Cl)O1]

2.2 Synthesis of Siloxane Compound (1)

The siloxane compound (1) is obtained by adding the cross-linking agent Y of the structural formulas (2) to (12) to the above-obtained siloxane precursor (A).

For example, the following silanolate compounds, each of which has a cross-linking group of the structural formula (7), that is, a benzocyclobutenyl group can be obtained as the siloxane compound (1) by reacting 4-bromobenzocyclobutene with an organic metal reagent and reacting the resulting metal-halogen exchange product with the siloxane precursor (A). More specifically, a benzocyclobutenyl lithium salt is first formed as a precursor compound for introducing the cross-linking group of the structural formula (7) by reaction of 4-bromobenzocyclobutene with alkyl lithium salt such as n-butyl lithium, tert-butyl lithium or methyl lithium as indicated in the following scheme (see Non-Patent Document 5).

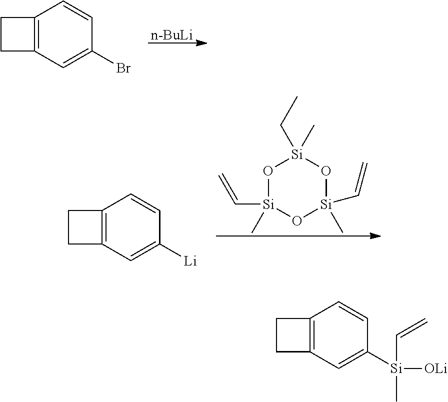

As the organic metal reagent, n-butyl lithium is preferably used in terms of availability. After the lithiation, the resulting benzocyclobutenyl lithium salt is reacted with hexamethylcyclotrisiloxane. A benzocyclobutenyl-containing siloxlithium compound is obtained through ring-cleavage reaction of the hexamethylcyclotrisiloxane.

By the same operation as above, siloxylithium compounds (A) to (E) can be synthesized from bromo compounds (a) to (e) through the following reaction routes, respectively.

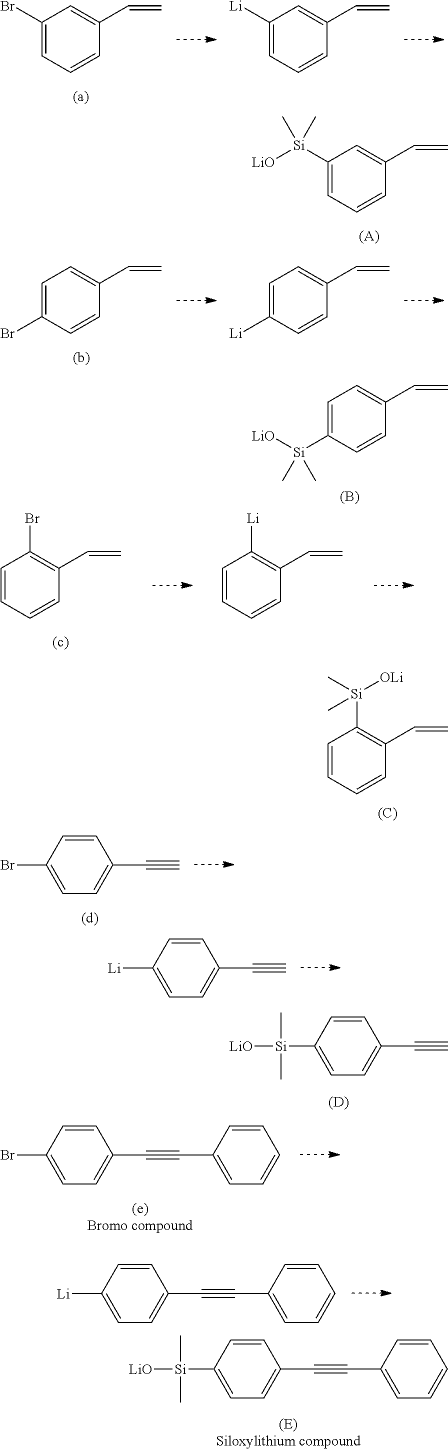

A silanolate compound having a benzocyclobutenyl group of the structural formula (7) is synthesized as one example of the siloxane compound (1) by reaction of the siloxane precursor (A) and the benzocyclobutenyl-containing siloxlithium compound as indicated in the following reaction scheme.

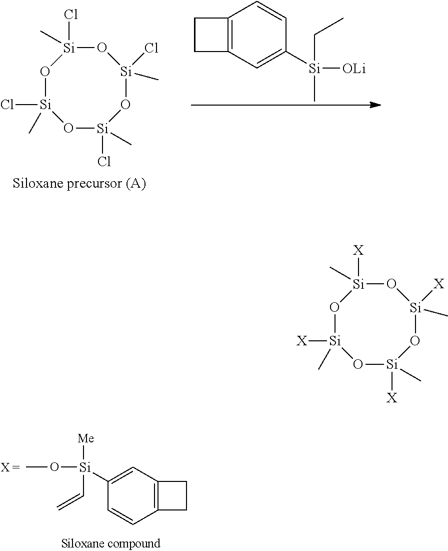

The siloxylithium compounds (A) to (E) can be converted to corresponding silanolate compounds (AA) to (EE) through chemical reactions by the same operation as above.

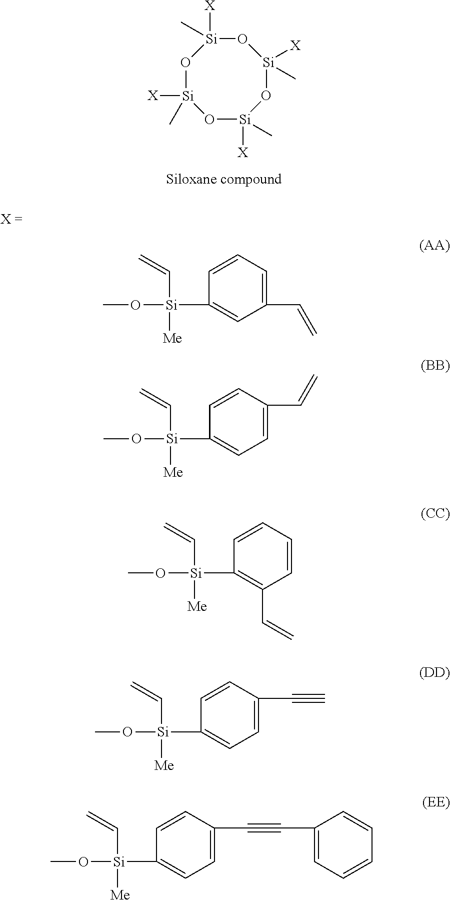

3. Use of Siloxane Compound (1) as Semiconductor Sealing Material

A sealing material for semiconductors is required to have strong adhesion to a metal wiring material over a wide temperature range. It is thus necessary to adjust the linear expansion coefficient of the sealing material in such a manner that the linear expansion coefficient of the sealing material becomes as close as that of the metal wiring material. There are a plurality of conceivable ways to cope with this requirement for use of the siloxane compound (1) as the sealing material.

One conceivable way is to mix the siloxane compound (1) with an inorganic filler. The linear expansion coefficient of the siloxane compound (1) can be adjusted to an arbitrary value by mixing the siloxane compound (1) with the inorganic filler such as silica or alumina. In the present invention, the siloxane compound (1) is liquid in a temperature range up to 60° C. and thus is easily mixable with the inorganic filler.

Another conceivable way is to utilize thermal addition polymerization. There arises a problem of bubble and volume contraction in the case of utilizing hydrolysis/dehydration-condensation of silicon alkoxide, typified by sol-gel reaction, as the final curing reaction in a polymerization process. Thus, thermal addition polymerization of the cross-linking group is utilized as the final curing reaction in the present invention. This thermal addition polymerization is considered as the suitable curing reaction system of the sealing material due to the fact that there is no need to use ultraviolet irradiation and curing catalyst in the thermal addition polymerization. Further, the cross-linking group Y is considered as the most preferable addition polymerization/cross-linking group due to the facts that: the cross-linking group Y goes through curing reaction at 350° C. or lower, i.e., in the heat resistant temperature range of power semiconductor materials; and the resulting cured product shows very high durability such as mass reduction rate of 10 mass % or lower in long-term heat resistance test at 250° C.

### EXAMPLES

The present invention will be described in more detail below with reference to the following examples. It should be understood that the following examples are illustrative and are not intended to limit the present invention thereto. Herein, samples of siloxane compounds and cured products thereof obtained in the respective examples and comparative examples were tested for their quality by the following methods.

[Test Methods]

<Measurement of Viscosity>

The viscosity of the siloxane sample was measured at 25° C. with the use of a rotating viscometer (product name “DV-II+PRO” manufactured by Brookfield Engineering Inc.) and a temperature control unit (product name “THERMOSEL” manufactured by Brookfield Engineering Inc.).

<Measurement of 5 Mass % Reduction Temperature>

Using a thermal mass-differential thermal analyzer (product name “TG8120” manufactured by Rigaku Corporation), the cured siloxane sample was heated from 30° C. at a temperature rise rate of 5° C./min under the flow of air at 50 ml/min. The temperature at which the mass of the cured siloxane sample was reduced by 5 mass % relative to that before the measurement was determined as 5 mass % reduction temperature.

1. Synthesis of Cross-Linking Group Precursors

A precursor compound A (Synthesis Example 1) for introducing a cross-linking group of the structural formula (7) to a siloxane precursor (A) and a precursor compound B (Synthesis Example 2) for introducing a cross-linking group of the structural formula (10) to a siloxane precursor (A) were first synthesized. The detailed synthesis procedures will be explained below.

### Synthesis Example 1

### Synthesis of Precursor Compound A for Introduction of Cross-Linking Group of Structural Formula (7)

Into a 1-L three-neck flask with a thermometer and a reflux condenser, 14.6 g (80.0 mmol) of 4-bromobenzocyclobutene and 50 g of diethyl ether were placed. The resulting solution inside the flask was cooled to −78° C. while stirring. After the inside temperature of the flask reached −78° C., 56 ml (90 mmol) of 1.6 mol/L solution of buthyl lithium in hexane was dropped into the solution over 30 minutes. After the completion of the dropping, the solution was further stirred for 30 minutes. Then, 6.89 g (26.7 mmol) of trimethyltrivinylcyclotrisiloxane was added to the solution. The solution was raised to room temperature while stirring. The solution was further stirred for 12 hours at room temperature. There was thus obtained the diethyl ether solution of the precursor compound of the formula (14) as indicated in the following reaction scheme.

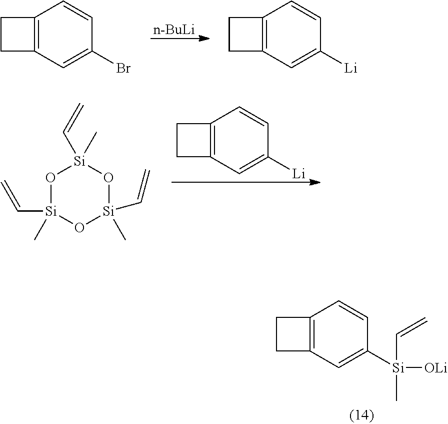

### Synthesis Example 2

### Synthesis of Precursor Compound B for Introduction of Cross-Linking Group of Structural Formula (10)

Into a 1-L three-neck flask with a thermometer and a reflux condenser, 20.6 g (80.0 mmol) of 4-bromodiphenylacetylene and 50 g of diethyl ether were placed. The resulting solution inside the flask was cooled to −78° C. while stirring. After the inside temperature of the flask reached −78° C., 56 ml (90 mmol) of 1.6 mol/L solution of buthyl lithium in hexane was dropped into the solution over 30 minutes. After the completion of the dropping, the solution was further stirred for 30 minutes. Then, 5.94 g (26.7 mmol) of hexamethylcyclotrisiloxane was added to the solution. The solution was raised to room temperature while stirring. The solution was further stirred for 12 hours at room temperature. There was thus obtained the diethyl ether solution of the precursor compound B of the formula (15) as indicated in the following reaction scheme.

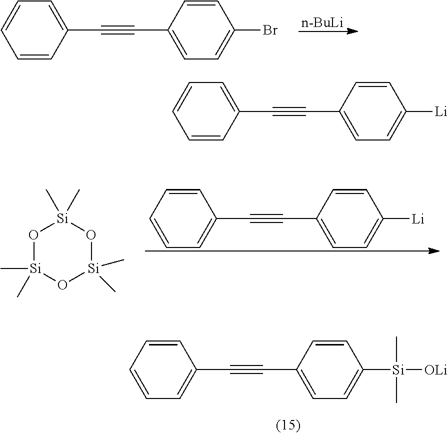

2. Synthesis of Siloxane Compound (1)

The siloxane compound (1) was synthesized by reacting each of the precursor compound A (Synthesis Example 1) and the precursor compound B (synthesis Example 2) with the siloxane precursor A. The detailed synthesis procedures of Examples 1 and 2 will be explained below.

### Example 1

### Synthesis of Siloxane Compound

Into a 300-mL three-neck flask with a thermometer and a reflux condenser, 50.0 g of tetrahydrofuran and 4.88 g (20.0 mmol) of tetramethyltetrahydrocyclotetrasiloxane were placed. The resulting solution inside the flask was cooled to −78° C. while stirring. After the inside temperature of the flask reached −78° C., 6.28 g (27.0 mmol) of trichloroisocyanuric acid was added to the solution. After the completion of the adding, the solution was further stirred at −78° C. for 30 minutes. The solution was raised to room temperature while stirring. The tetrahydrofuran solution was obtained upon filtering out any insoluble deposit.

The tetrahydrofuran solution was then dropped into the diethyl ether solution of the precursor compound A, which had been obtained in Synthesis Example 1 and cooled to 3° C., gradually over 10 minutes. After the completion of the dropping, the mixed solution was raised to room temperature while stirring. The mixed solution was kept stirred for 2 hours at room temperature. After the completion of the stirring, the mixed solution was admixed with 50 g of diisopropyl ether and 50 g of pure water and separated into two phases by stirring for 30 minutes. The aqueous phase was separated from the organic phase. The organic phase was then washed three times with 50 g of distilled water and dried with 10 g of magnesium sulfate. After the removal of the magnesium sulfate, the organic phase was concentrated under a reduced pressure at 150° C./0.1 mmHg.

As indicated in the following reaction scheme, the siloxane compound of the structural formula (16) (R¹=CH₃; R⁴=CH₃; R⁵=vinyl; Y=cross-linking group of the structural formula (7); m=4; and n=0) was thus obtained in colorless transparent oily form in an amount of 16.5 g and at a yield of 83%. The viscosity of this oily compound was determined to be 1700 mPa·s by viscosity measurement.

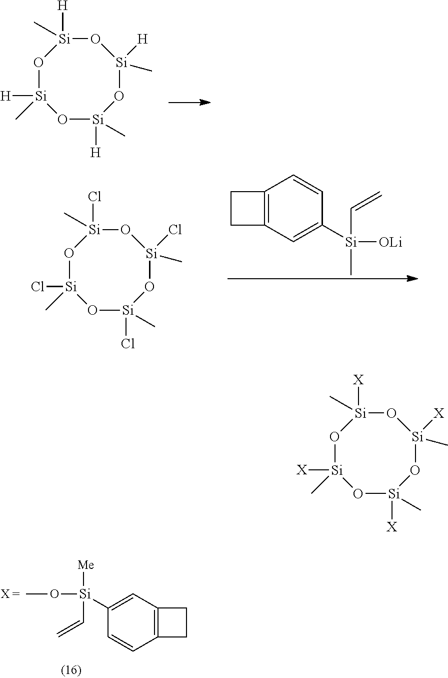

The obtained siloxane compound was poured into a mold of silicon (product name “SH9555” manufactured by Shin-Etsu Chemical Co., Ltd.) and heated at atmospheric pressure and at 250° C. for 1 hour, thereby forming a cured product of 2 mm thickness with no bubble and cracking. The 5 mass % reduction temperature of the cured product was 430° C.

### Example 2

The synthesis was performed in the same manner as in Example 1 using the diethyl ether solution of the precursor compound B obtained in Synthesis Example 2. As indicated in the following reaction scheme, the siloxane compound of the structural formula (17) (R¹, R⁴, R⁵=CH₃; Y=cross-linking group of the structural formula (10); m=4; and n=0) was obtained in colorless transparent oily form in an amount of 19.9 g and at a yield of 80%. The viscosity of this oily compound was determined to be 3600 mPa·s by viscosity measurement.

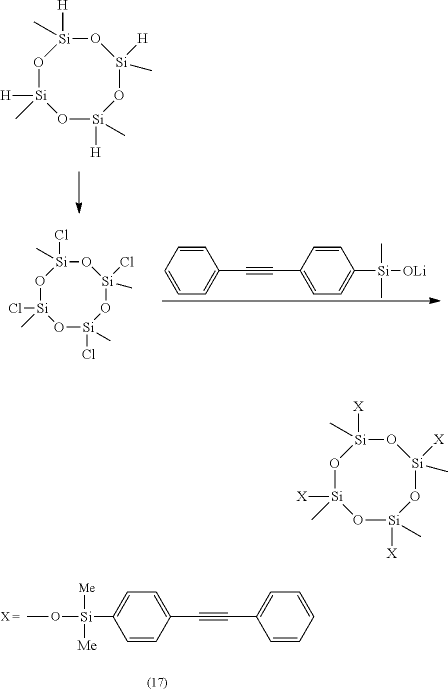

The obtained siloxane compound was poured into a mold of silicon (product name “SH9555” manufactured by Shin-Etsu Chemical Co., Ltd.) and heated at atmospheric pressure and at 330° C. for 1 hour, thereby forming a cured product of 2 mm thickness with no bubble and cracking. The 5 mass % reduction temperature of the cured product was 450° C.

### Comparative Example 1

Into a 300-mL three-neck flask with a thermometer, 50.0 g of tetrahydrofuran, 4.88 g (20.0 mmol) of tetramethyltetrahydrocyclotetrasiloxane, 10.42 g (80.0 mmol) of 4-vinylbenzocyclobutene and 0.10 g of xylene solution of platinum-divinyltetramethyldisiloxane mixture (platinum content: 2%) were placed. The resulting solution was stirred at room temperature for 3 hours and then concentrated under a reduced pressure at 150° C./0.1 mmHg. As indicated in the following reaction scheme, the siloxane compound of the structural formula (18) was obtained in colorless transparent oily form in an amount of 12.2 g and at a yield of 80%. The viscosity of this oily compound was determined to be 2800 mPa·s by viscosity measurement.

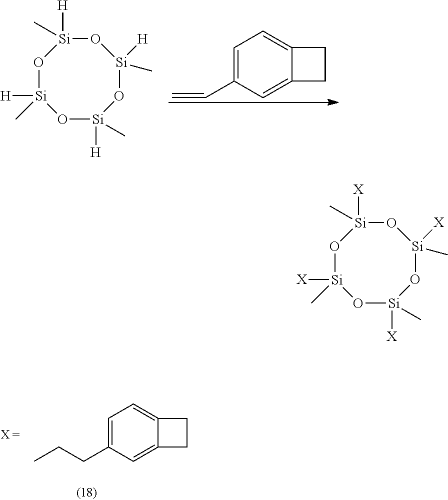

The obtained siloxane compound was poured into a mold of silicon (product name “SH9555” manufactured by Shin-Etsu Chemical Co., Ltd.) and heated at atmospheric pressure and at 250° C. for 1 hour, thereby forming a cured product of 2 mm thickness with no bubble and cracking. The 5 mass % reduction temperature of the cured product was 400° C.

### Comparison of 5 Mass % Reduction Temperature

TABLE 1

| | Cured product: 5 mass % reduction temperature |
|---|---|
| Example 1 | 430° C. |
| Example 2 | 450° C. |
| Comparative Example 1 | 400° C. |

As is seen from TABLE 1, the 5 mass % reduction temperature of each of the cured products of the siloxane compounds (1) of Examples 1 and 2 was higher than that of Comparative Example 1. The reason for this is assumed that the cured products of the siloxane compounds (1) of Examples 1 and 2 had higher heat resistance than that of Comparative Example 1 because each of the siloxane compounds (1) of Examples 1 and 2 had no ethylene group that would cause deterioration in heat resistance.

Although the present invention has been described above with reference to the above specific exemplary embodiment, various modifications and variations of the embodiment described above can be made based on the common knowledge of those skilled in the art without departing from the scope of the present invention.

1.-5. (canceled)

6. A siloxane compound of the general formula (1): 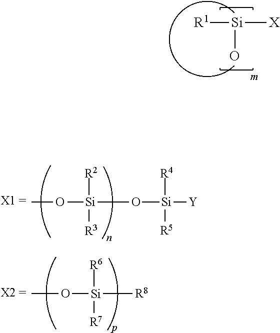
where X are each independently either X1 or X2 with the proviso that at least one of X is X1; R¹ to R⁸ are each independently a hydrogen atom, a C₁-C₈ alkyl, alkenyl or alkynyl group, a phenyl group or a pyridyl group; each of R¹ to R⁵ may have a carbon atom replaced by an oxygen atom and may have an ether bond, a carbonyl group or an ester bond in a structure thereof; m is an integer of 3 to 8; n is an integer of 0 to 9; p is 0 or 1; and Y are each independently a cross-linking group.

7. The siloxane compound according to claim 6, wherein Y are each independently a cross-linking group selected from the group consisting of those of the structural formulas (2) to (12):

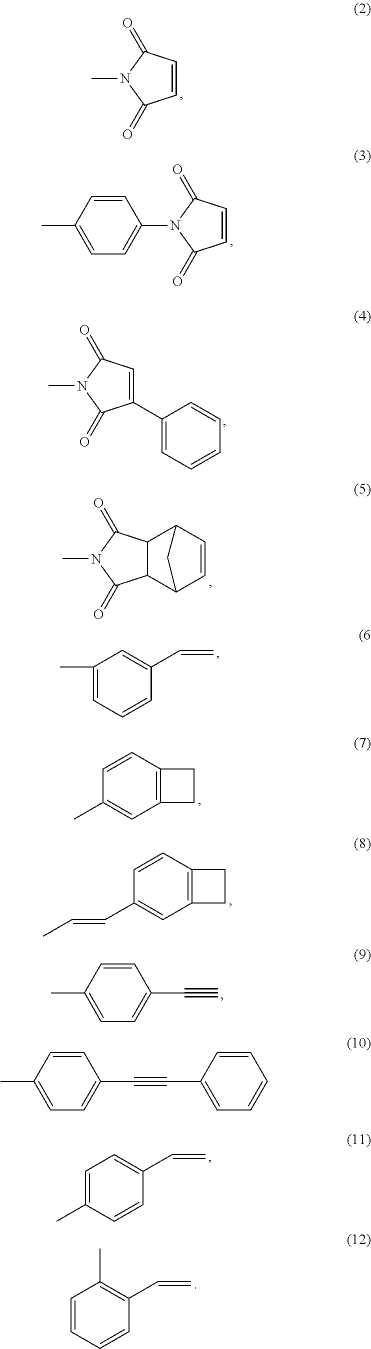

8. The siloxane compound according to claim 6, wherein all of R¹ to R⁸ are methyl, n is 0 and p is 0 or 1.

9. A cured product obtained by reaction of the cross-linking group of the siloxane compound according to claim 6.

10. A sealing material containing the cured product according to claim 9.
